(19) United States
(12) Patent Application Publication
(10) Pub. No.: US 2005/0268186 A1
(43) Pub. Date: Dec. 1, 2005

(54) Semiconductor wafer with test circuit and manufacturing method

(76) Inventors: Wei-Jung Chen, Hsinchu (TW); Yung-Ching Chang, Hsinchu (TW); Jaw-Shin Huang, Hsinchu (TW); Cheng-Yu Fang, Hsinchu (TW); Chien-Peng Yu, Hsinchu (TW)

Correspondence Address: RAYMOND Y. CHAN, 108 N. YNEZ AVE., SUITE 128, MONTEREY PARK, CA, 91754, US

(21) Appl. No.: 10/841,915

(22) Filed: May 6, 2004

(51) Int. Cl. G11C 29/00; G01R 31/28

(52) U.S. Cl. 714/721

(57) ABSTRACT

A semiconductor wafer includes a wafer body, a plurality of dies spacedly and alignedly formed on the wafer body to define a scribe line as a margin formed between each two the dies, wherein at least one of the dies is formed as a tested die having a terminal pad for measuring a voltage of the tested die via a measuring tool, and a test circuit having an output end and an input end electrically extended from an internal circuit of the tested die. An output impedance of the test circuit is relatively smaller than an impedance of the measuring tool, such that the voltage of the tested die adapted for being precisely measured when testing terminals of the measuring tool are electrically pointed at the tested die and the output end of the test circuit respectively.

### BACKGROUND OF THE PRESENT INVENTION

1. Field of Invention

The present invention relates to semiconductors, and particularly to a semiconductor wafer which comprises a test circuit electrically connected with the die of the semiconductor wafer to precisely measure the reference voltage of the die.

2. Description of Related Arts

A conventional semiconductor wafer comprises a wafer body and a plurality of dies spacedly formed on the wafer body to define a scribe line as a margin between each two dies. Accordingly, each of the dies, which is also called as chip, is an integrated circuit consisting of silicon based substrate.

Before each of the dies is cut into an individual component, a wafer test must be performed to ensure each of the dies is functioning in an optimum condition. Generally, each of the dies comprises a plurality of bond pads and a plurality of terminal pads spacedly formed within the die, wherein the terminal pads can be test pads for measuring the reference voltage of the die via a measuring tool, such as probe card, or trim pads for trimming the reference voltage of the die and the reference function thereof.

Accordingly, the die is commonly embodied as an IC for a portable electronic device, such as PDA or mobile phone, wherein such portable electronic is powered by battery. Therefore, the electrical usage of the die is one of the major factors to determine the power usage of the portable electronic device. In other words, the current corresponding with the total device should be relatively small. Accordingly, it is important how to accurately measure the reference voltage the die for the portable electronic device.

However, when measuring the reference voltage of the die, the current corresponding with the reference voltage is relatively small such that the output impedance of the die will be relatively large. Therefore, when using the probe card as the measuring tool to measure the voltage of the die, the parasitic impedance of the probe card will substantially affect the actual output impedance of the die. In other words, when the current is relatively small, the voltage measurement of the semiconductor wafer will be inaccurate.

### SUMMARY OF THE PRESENT INVENTION

A main object of the present invention is to provide a semiconductor wafer which comprises a test circuit electrically connected with the terminal pad of the semiconductor to precisely measure the voltage thereof.

Another object of the present invention is to provide a semiconductor wafer, wherein an output impedance of the test circuit is relatively smaller than the impedance of the probe card as the measuring tool so as to minimize the affect of the parasitic impedance of the probe card during measurement.

Another object of the present invention is to provide a semiconductor wafer, wherein an input impedance of the test circuit is relatively larger than the impedance of the die so as to minimize the affect of the voltage measurement of the die.

Another object of the present invention is to provide a semiconductor wafer, wherein the test circuit is printed on the scribe line of the semiconductor wafer such that when the die is cut off from the semiconductor wafer along the scribe line, the test circuit is removed from the die. In other words, when the die is installed into the electronic device, no electrical energy of the die is used by the test circuit since the test circuit is already removed from the die.

Another object of the present invention is to provide a manufacturing method of providing a test circuit on the semiconductor wafer, wherein the test circuit can be easily printed on the scribe line of the semiconductor wafer to electrically connect to the die. Therefore, the voltage of the die can be precisely measured by incorporating with the test circuit.

Another object of the present invention is to provide a semiconductor wafer, wherein the test circuit is a simple electric circuit, such as an operational amplifier, formed on the semiconductor wafer such that no significant manufacturing cost of the semiconductor wafer is increased when incorporating with the test circuit.

Accordingly, in order to accomplish the above objects, the present invention provides a semiconductor wafer, comprising:
a wafer body;
a plurality of dies spacedly and alignedly formed on the wafer body to define a scribe line as a margin formed between each two dies, wherein at least one of the dies is formed as a tested die having a terminal pad for measuring a voltage of the tested die; and
a test circuit, which is provided on the wafer body to electrically connect with the tested die, having an output end and an input end electrically extended from an internal circuit of the tested die, wherein an input impedance of the input end of the test circuit is relatively larger than an output impedance of the tested die;
thereby, an output impedance of the test circuit is relatively smaller than an impedance of a measuring tool such that by electrically pointing testing terminals of the measuring tool at the tested die and the output end of the test circuit respectively, the measuring tool is adapted to precisely measure the voltage of the tested die.

These and other objectives, features, and advantages of the present invention will become apparent from the following detailed description, the accompanying drawings, and the appended claims.

### BRIEF DESCRIPTION OF THE DRAWINGS

FIG. 1 is a perspective view of a semiconductor wafer with a detachable test circuit according to a preferred embodiment of the present invention.

FIG. 2 is a perspective view of the die electrically connected with the test circuit of the semiconductor wafer according to the above preferred embodiment of the present invention.

### DETAILED DESCRIPTION OF THE PREFERRED EMBODIMENT

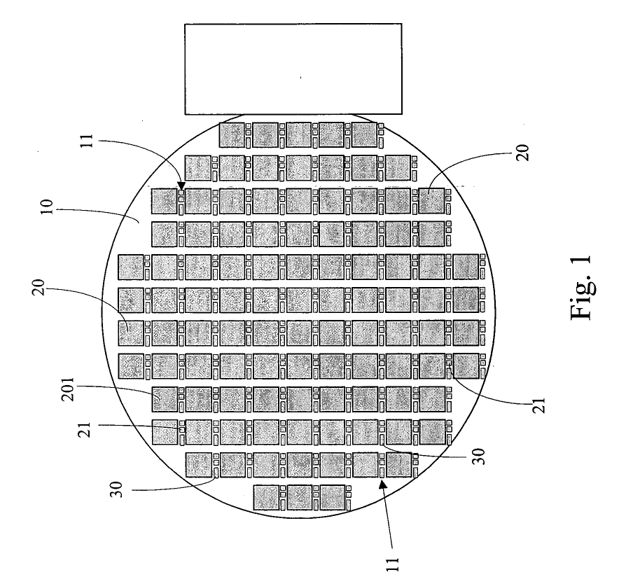

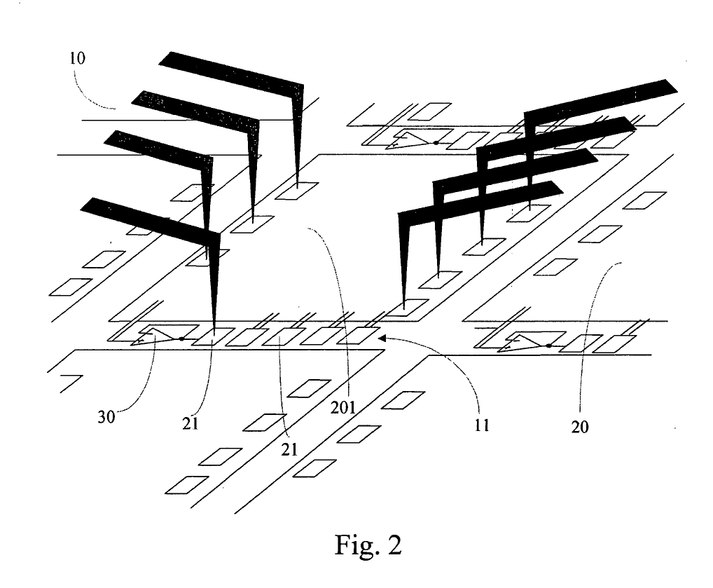

Referring to FIGS. 1 and 2 of the drawings, a semiconductor wafer according to a preferred embodiment of the present invention is illustrated, wherein the semiconductor wafer comprises a wafer body 10 and a plurality of dies 20 spacedly and alignedly formed on the wafer body 10 to define a scribe line 11 as a margin formed between each two dies 20, wherein at least one of the dies 20 is formed as a tested die 201 having a terminal pad 21 for measuring a voltage of the tested die 201. Also, the terminal pad 21 can be formed at the scribe line 11.

The semiconductor wafer further comprises a test circuit 30, which is provided on the wafer body 10 to electrically connect with the tested die 201, having an output end and an input end electrically extended from an internal circuit of the tested die 201, wherein an input impedance of the input end of the test circuit 30 is relatively larger than an output impedance of the tested die 201.

Accordingly, an output impedance of the test circuit 30 is relatively smaller than an impedance of a measuring tool such that by electrically pointing testing terminals of the measuring tool at the tested die 201 and the output end of the test circuit 30 respectively, the measuring tool is adapted to precisely measure the voltage of the tested die 201.

According to the preferred embodiment, each of the dies 201 is constructed by a plurality of integrated circuits electrically connected with the test circuits 30 respectively wherein the measuring tool is arranged to test the actual voltage of each of the dies 201.

The terminal pad 21 is embodied as a trim pad electrically extended from of the integrated circuit of the tested die 201. Accordingly, a trim fuse is electrically extended from the trim pad of the terminal pad 21 such that the tested die 201 is adapted to be trimmed to generate a reference voltage and the reference function of the tested die 201. Alternatively, the terminal pad 21 can be a test pad or test pads for electrically coupling with the measuring tool to measure the voltage of the tested die 201.

Generally speaking, all the dies 20 on the wafer body 10 should be tested to ensure the dies 20 are functioning in an optimum condition. However, at least one of the dies 20 can be selected to be the tested die 201 for voltage measurement and adjustment.

As shown in FIG. 2, the test circuit 30 is printed on the scribe line 11 of the wafer body 10 wherein the input end of the test circuit 30 is extended from the scribe line 11 to electrically connect with an internal circuit of the tested die 201 while the output end of the test circuit 30 is formed along the scribe line 11. Therefore, after measuring the voltage of the tested die 201, the test circuit 30 is removed from the tested die 201 when the tested die 201 is cut off from the wafer body 10 along the scribe line 11.

It is worth to mention that when the test circuit 30 is removed from the tested die 201, the tested die 201 is formed as an individual chip to be installed into an electronic device, such as PDA or mobile phone. Therefore, when the tested die 201 is installed into the electronic device, no electrical energy of the tested die 201 is used by the test circuit 30 since the test circuit 30 is already removed from the tested die 201. In addition, the detachment of the test circuit 30 is easy that the removing operation and the assembling operation of the test circuit 30 can be preformed at the same time.

According to the preferred embodiment, the test circuit 30 is an operational amplifier (OP AMP), as shown in FIG. 2, wherein the operational amplifier of the test circuit 30 comprises a transistor input stage. The transistor input stage can be the Metal-Oxide-Semiconductor Field-Effect-Transistor (MOSFET) or the bipolar junction transistor (BJT). Preferably, the MOSFET is used for the operational amplifier because the MOSFET provides larger input impedance.

The input impedance of the test circuit 30 is relatively larger than the impedance of the tested die 201 to minimize the affect of the voltage measurement of the tested die 201 while the output impedance of the test circuit 30 is relatively smaller than the impedance of the measuring tool such that there is no significant affect of the impedance of the measuring tool during measurement.

The probe card is commonly used as the measuring tool to measure the voltage of the tested die 201. Accordingly, the output impedance of the test circuit 30 is relatively smaller than the parasitic impedance of the probe card so as to minimize the affect of the parasitic impedance of the probe card during measurement.

For example, the current passing through the tested die 201 is approximately 3 uA and the current passing through to the internal reference circuit is approximately 500 nA, wherein the tolerance of the test circuit is about 1% such that the parasitic impedance of the probe card is at least 400 mega ohms when 2V voltage is used.

According to the preferred embodiment, the present invention also provides method of measuring a voltage of a die via the probe card, wherein the method comprises the following steps.

(1) Form the test circuit 30 on the semiconductor wafer to electrically connect with the tested die 201, wherein the test circuit 30 has an output end and an input end electrically extended from an internal circuit of the tested die 201, wherein an input impedance of the input end of the test circuit 30 is relatively larger than an impedance of the tested die 201, wherein an output impedance of the test circuit 30 is relatively smaller than an impedance of a parasitic impedance of the probe card.

(2) Electrically point testing terminals of the probe card at the tested die 201 and the output end of the test circuit 30 respectively to precisely measure the voltage of the tested die 201.

One skilled in the art will understand that the embodiment of the present invention as shown in the drawings and described above is exemplary only and not intended to be limiting.

It will thus be seen that the objects of the present invention have been fully and effectively accomplished. It embodiments have been shown and described for the purposes of illustrating the functional and structural principles of the present invention and is subject to change without departure from such principles. Therefore, this invention includes all modifications encompassed within the spirit and scope of the following claims.

1. A semiconductor wafer, comprising:
a wafer body;
a plurality of dies spacedly and alignedly formed on said wafer body to define a scribe line as a margin formed between each two said dies, wherein at least one of said dies is formed as a tested die having a terminal pad for measuring a voltage of said tested die via a measuring tool; and
a test circuit, which is provided on said wafer body to electrically connect with said tested die, having an output end and an input end electrically extended from an internal circuit of said tested die, wherein an output impedance of said test circuit is relatively smaller than an impedance of said measuring tool, such that said voltage of said tested die adapted for being precisely measured when testing terminals of said measuring tool are electrically pointed at said tested die and said output end of said test circuit respectively.

2. A semiconductor wafer, as recited in claim 1, said input end of said test circuit has a predetermined input impedance relatively larger than an impedance of said tested die.

3. A semiconductor wafer, as recited in claim 1, wherein said test circuit is printed on said scribe line such that said input end of said test circuit is extended from said scribe line to electrically connect with said tested die while said output end of said test circuit is formed along said scribe line, such that said test circuit is removed from said tested die when said tested die is cut off from said wafer body.

4. A semiconductor wafer, as recited in claim 1, wherein said test circuit is an operational amplifier.

5. A semiconductor wafer, as recited in claim 3, wherein said test circuit is an operational amplifier.

6. A semiconductor wafer, as recited in claim 4, wherein said operational amplifier comprises a Metal-Oxide-Semiconductor Field-Effect-Transistor (MOSFET) input stage that provides larger input impedance for said test circuit with respect to said tested die.

7. A semiconductor wafer, as recited in claim 5, wherein said operational amplifier comprises a Metal-Oxide-Semiconductor Field-Effect-Transistor (MOSFET) input stage that provides larger input impedance for said test circuit with respect to said tested die.

8. A semiconductor wafer, as recited in claim 4, wherein said operational amplifier comprises a bipolar junction transistor (BJT) input stage that provides larger input impedance for said test circuit with respect to said tested die.

9. A semiconductor wafer, as recited in claim 5, wherein said operational amplifier comprises a bipolar junction transistor (BJT) input stage that provides larger input impedance for said test circuit with respect to said tested die.

10. A method of measuring a voltage of a die via a probe card, comprising the steps of:
(a) forming a test circuit on a semiconductor wafer having at least said die formed thereon as a tested die, wherein said test circuit has an output end and an input end electrically extended from said tested die, wherein an output impedance of said test circuit is relatively smaller than a parasitic impedance of said probe card; and
(b) electrically pointing testing terminals of said probe card at said tested die and said output end of said test circuit respectively to precisely measure said voltage of said tested die.

11. The method as recited in claim 10, in step (a), further comprising a step of presetting an input impedance of said input end of said test circuit that said input impedance thereof is relatively larger than an impedance of said tested die.

12. The method as recited in claim 11, in step (a), wherein said test circuit is printed on said scribe line such that said input end of said test circuit is extended from said scribe line to electrically connect with said tested die while said output end of said test circuit is formed along said scribe line, such that said test circuit is removed from said tested die when said tested die is cut off from said semiconductor wafer.

13. The method, as recited in claim 10, wherein said test circuit is an operational amplifier.

14. The method, as recited in claim 12, wherein said test circuit is an operational amplifier.

15. The method, as recited in claim 13, wherein said operational amplifier comprises a Metal-Oxide-Semiconductor Field-Effect-Transistor (MOSFET) input stage.

16. The method, as recited in claim 14, wherein said operational amplifier comprises a Metal-Oxide-Semiconductor Field-Effect-Transistor (MOSFET) input stage.

17. The method, as recited in claim 13, wherein said operational amplifier comprises a bipolar junction transistor (BJT) input stage.

18. The method, as recited in claim 14, wherein said operational amplifier comprises a bipolar junction transistor (BJT) input stage.
